(19) United States
(12) Patent Application Publication
(10) Pub. No.: US 2016/0211258 A1
(43) Pub. Date: Jul. 21, 2016

(54) Reverse-Conducting Gated-Base Bipolar-Conduction Devices and Methods with Reduced Risk of Warping

(71) Applicant: MaxPower Semiconductor Inc., San Jose, CA (US)

(72) Inventors: Jun Zeng, Torrance, CA (US); Mohamed N. Darwish, Campbell, CA (US)

(21) Appl. No.: 14/988,646

(22) Filed: Jan. 5, 2016

Related U.S. Application Data
(60) Provisional application No. 62/099,710, filed on Jan. 5, 2015.

(51) Int. Cl. H01L 27/06; H01L 29/16; H01L 29/66; H01L 29/06; H01L 29/739; H01L 29/872

(52) U.S. Cl. CPC H01L 27/0664; H01L 29/7397; H01L 29/872; H01L 29/66348; H01L 29/66143; H01L 29/0661; H01L 29/16

(57) ABSTRACT

Reverse-conducting IGBTs where the collector side includes diode terminal regions, and the semiconductor material is much thicker through the diode terminal regions than it is through the collector regions. This exploits the area fraction which is taken up by the diode terminal regions to provide increased rigidity for the wafer, and thus avoid warping.

### CROSS-REFERENCE

Priority is claimed from U.S. patent application 62/099,710 filed Jan. 5, 2015, which is hereby incorporated by reference.

### BACKGROUND

The present application relates to power devices using bipolar conduction with back-surface injection of minority carriers, and more particularly to insulated-gate bipolar transistors which include a reverse-conduction diode (“RC-IGBTs”).

Note that the points discussed below may reflect the hindsight gained from the disclosed applications, and are not necessarily admitted to be prior art.

An insulated-gate bipolar transistor (IGBT) is a three-terminal power semiconductor device primarily used as an electronic switch. Bipolar transistor action is initiated by a MOS control gate. (Conceptually, the IGBT can be thought of as a merged device in which a field-effect control transistor controls base drive to a vertical bipolar transistor.) IGBTs combine many of the advantages of power field-effect transistors with those of power bipolar transistors. IGBTs are used to switch electric power in many modern appliances: variable-frequency drives (VFDs), electric cars, trains, variable speed refrigerators, lamp ballasts, air-conditioners, and even stereo systems with switching amplifiers. Amplifiers that use IGBTs can synthesize complex waveforms with pulse-width modulation and low-pass filters.

Currently, state of the art of IGBTs are utilizing so-called Field Stop (“FS”), or Light Punch-Through (“LPT”), or Soft Punch-Trough (“SPT”) techniques to optimize the n-type buffer layer to prevent high electric fields near the P-type collector (anode) region. These techniques are respectively described in the following publications, all of which are hereby incorporated by reference: T. Laska, et al., “Short Circuit Properties of Trench/Field Stop IGBTs Design Aspects for a Superior Robustness”, Proc. ISPSD 2002; H. K. Nakamura, et al., “Advanced Wide Cell Pitch IGBT Having Light Punch Through (LPT) Structures”, Proc. ISPSD 2002; M. Rahimo, et al., “Extending the Boundary Limits of High Voltage IGBTs and Diodes to above 8KV”, Proc. ISPSD 2002.

IGBTs with an accurate design of the n-type buffer layer, combined with a very thin (“transparent”) P+ collector, have very promising trade-off characteristics in terms of device breakdown voltage, the on-state losses, and the switching losses. The unit cell structures of this kind of advanced IGBTs are shown in FIG. 2A and FIG. 2B.

FIG. 2A shows a conventional field-stop IGBT (FS-IGBT) without reverse conduction capability (since this device does not include a body diode). FIG. 2B shows a modified conventional structure with reverse-conduction (“RC”) capability. This is a conventional Field Stop RC-IGBT with the “shorted anode” structure for creating the capability of reverse conduction through the body diode when the device is in free-wheeling operation.

In both of these structures, the front-surface elements overlie an n-type drift region 200, and include an insulated trench gate 230, a shallow n++ source region 242, a p-type emitter region 244, and a p-type body region 246 which surrounds the emitter region 244. In FIG. 2A, the back-surface structures include only an n-type buffer layer 210, which is more heavily doped than the drift region 200, and a thin p+ collector region 220. Collector-side metallization 202 makes ohmic contact to the collector region 220.

The device of FIG. 2B has a different back-surface structure. Here the collector region 220 does not cover the entire back surface. Instead, at some locations, an n+diode contact region 212 lies under the buffer layer 210.

In order to optimize these structures for best performance, the depths (or thicknesses) of the N-buffer layer and the P+ anode are very critical. The depth of the N-buffer is normally in the range of couple microns (˜2 um) and the depth of P+ anode is less than one micron (˜0.5 um). The current fabrication process for forming these layers with such small dimensions is to grind an N− wafer down to the proper thickness. For example, for a 600V FS-IGBT the wafer thickness is about 70 um, and for 1200V FS-IGBT the wafer thickness is about 110 um.

Then, the constructions of the N-buffer and P+ anode are accomplished by implants of n-type dopant (such as Phosphorus) and p-type dopant (such as Boron) from the wafer backside, with or without masking. The activation of these dopants is either performed by laser annealing or furnace annealing. However, the thermal budget of these annealing processes is very critical for achieving good performance with minimum deviation, and must be precisely controlled in order to minimize dopant redistribution and changes in layer depths during the annealing process.

Nevertheless, carrying out these process steps on a thin wafer is very challenging from a manufacturing point of view. It is well known that thin wafers are less stable and more vulnerable to stresses, breakage and warping during processing. These events can occur not only during the substrate grinding but also at the subsequent process steps including implant, anneal and etch as well as masking. The current technique to improve these issues is to use temporary wafer bonding with a special wafer support system and carrier. Unfortunately, these techniques add complexity to the fabrication process and increase the manufacturing cost.

### Reverse-Conducting Gated-Base Bipolar-Conduction Devices and Methods with Reduced Risk of Warping

The present application discloses new approaches to implementing IGBTs (and analogous devices) with reverse conduction (“RC”) capability, particularly where a thin buffer layer is used over a thin collector region. The present inventors have realized that, since the diode-terminal areas (on the back surface) which provide the reverse-conduction diode are not required to have the same precise control of dopant distribution as the collector areas (on the same surface), additional thickness of semiconductor material in these areas can be used as mechanical support regions to avoid warping problems. Thus the collector area can be optimized to use precise control of the buffer and collector areas, and a small total thickness of semiconductor material, without the disadvantages of processing a very thin wafer.

Several different ways to implement these concepts are disclosed.

### BRIEF DESCRIPTION OF THE DRAWINGS

The disclosed applications will be described with reference to the accompanying drawings, which show important sample embodiments and which are incorporated in the specification hereof by reference, wherein:

FIGS. 1A, 1B, 1C, 1D, 1E, and 1F show six implementations of a new reverse-conducting field-stop IGBT with thicker semiconductor material in diode-terminal regions than in collector regions.

FIG. 2A shows a conventional field-stop IGBT (FS-IGBT) without reverse conduction capability, and FIG. 2B shows a different conventional structure with reverse-conduction (“RC”) capability.

FIGS. 3, 4, and 5 show a sequence of steps which can be used to fabricate the structures of FIGS. 1A-1F.

FIG. 6 shows an implementation which uses a Schottky contact collector.

FIG. 7 shows the distribution of current flow in an example of one of the new devices.

FIG. 8 compares the forward characteristics of new and conventional Field Stop RC-IGBT devices.

FIG. 9 compares the forward conduction I-V characteristics of a conventional IGBT, a VDMOST, and the new device.

FIG. 10 shows a further implementation of the new IGBT, using double buffer layers.

FIG. 11 shows a further implementation of the new IGBT, using triple-buffer layers having a segmented configuration.

FIGS. 12 and 13 show further implementations, using a more advanced IGBT with P++and N++nano-layers.

FIGS. 14 and 15 show further implementations, using a Schottky contact collector.

### DETAILED DESCRIPTION OF SAMPLE EMBODIMENTS

The numerous innovative teachings of the present application will be described with particular reference to presently preferred embodiments (by way of example, and not of limitation). The present application describes several applications, and none of the statements below should be taken as limiting the claims generally.

The present application discloses new approaches to implementing IGBTs (and analogous devices) with reverse conduction (“RC”) capability, particularly where a buffer layer is used over the collector (anode) region. These approaches are applicable to Field Stop (FS), or Light Punch-Through (LPT), or Soft Punch-Through (SPT) techniques, especially when a thin (or “transparent”) collector layer is used.

In this application, new fabrication device structures and processes are disclosed to address this challenge. Making use of the new techniques, an advanced FS-IGBT can be produced without the need of thinning substrate and special wafer supporting system or laser annealing. Additionally, the device structure leads to a significant improvement on the trade-off between the forward current voltage drop, VCEsat, and the “negative differential resistance” (NDR) issue due to the “shorted anode” structure in the RC-IGBT.

These final device structures have the Field Stop layer and the transparent P+ anode residing at the trench bottom floor with the thick N+ substrate remain to form the reverse conduction area or the “anode-short” layer. In addition, since the remaining N+ substrate has a normal thickness, it naturally becomes as a mechanical support to the whole wafer. Furthermore, the remaining N+ substrate also leads to the final device having a higher thermal capacitance compared to a thin substrate. As a result, the transient electro-thermal characteristic is expected to be superior compared to the conventional thin wafer FS-IGBT because of its higher thermal capacitance.

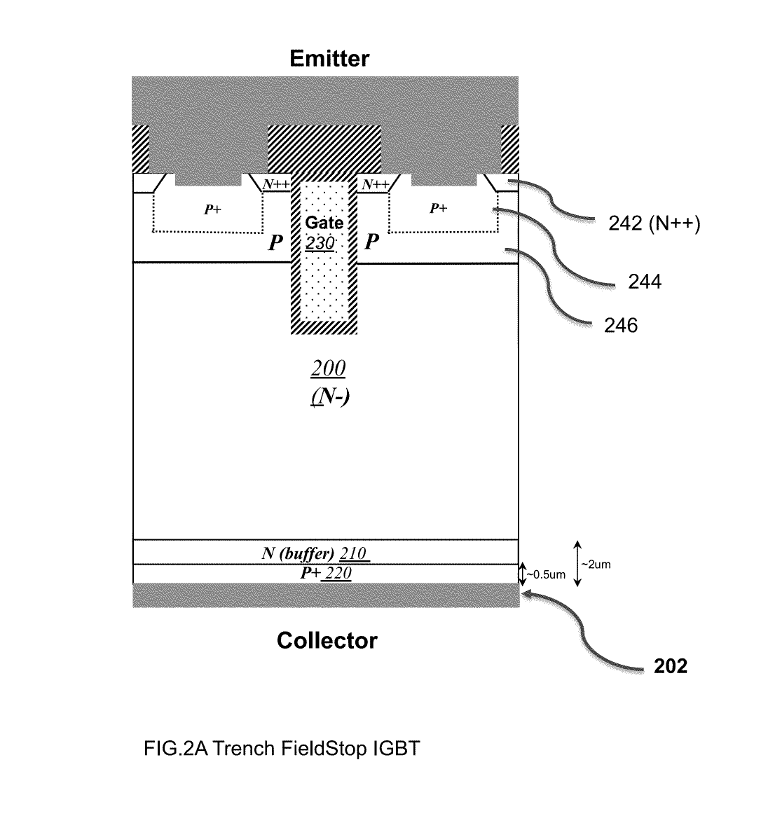

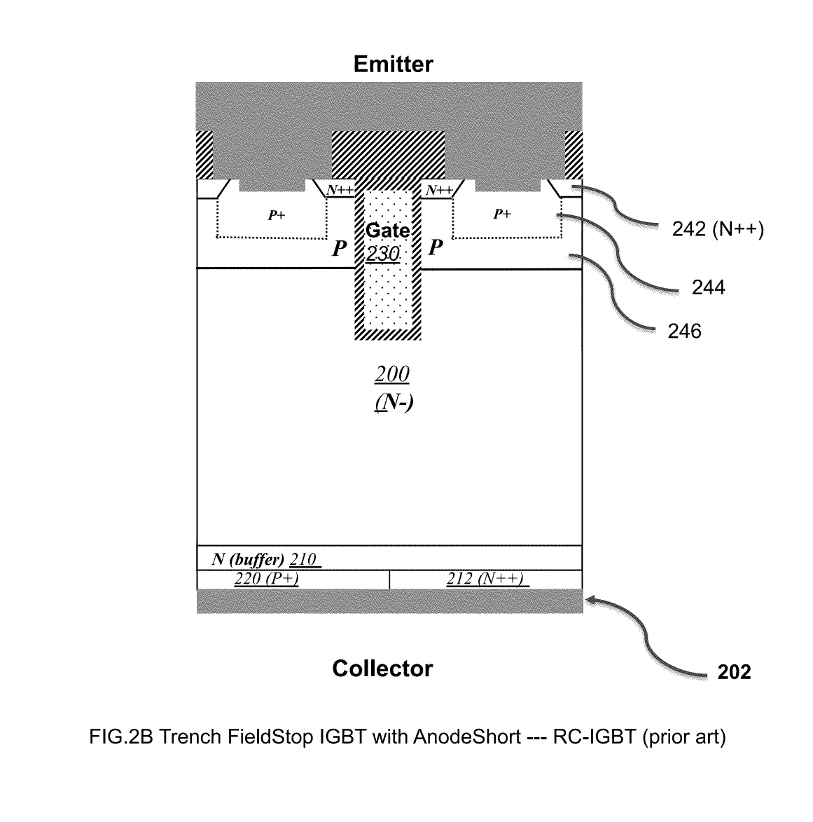

In the examples given, these structures generally have the same front-surface structures as the conventional devices of FIGS. 2A and 2B. However, the back-surface structures are quite different.

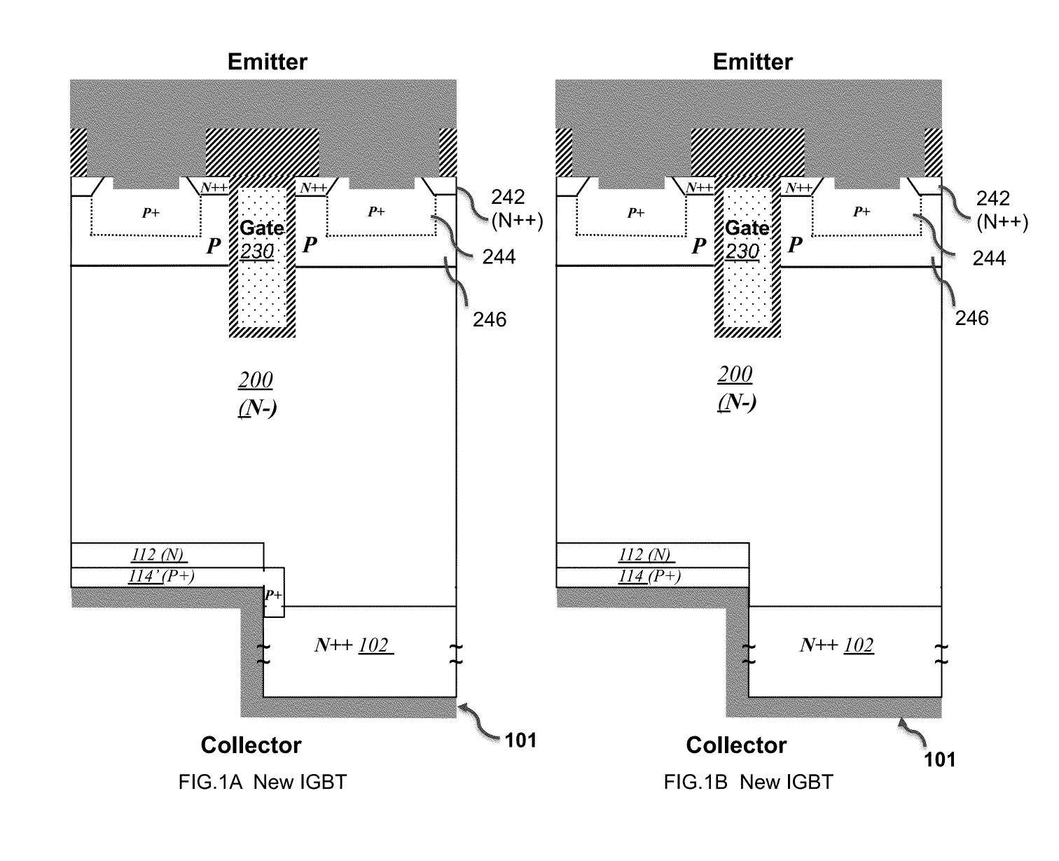

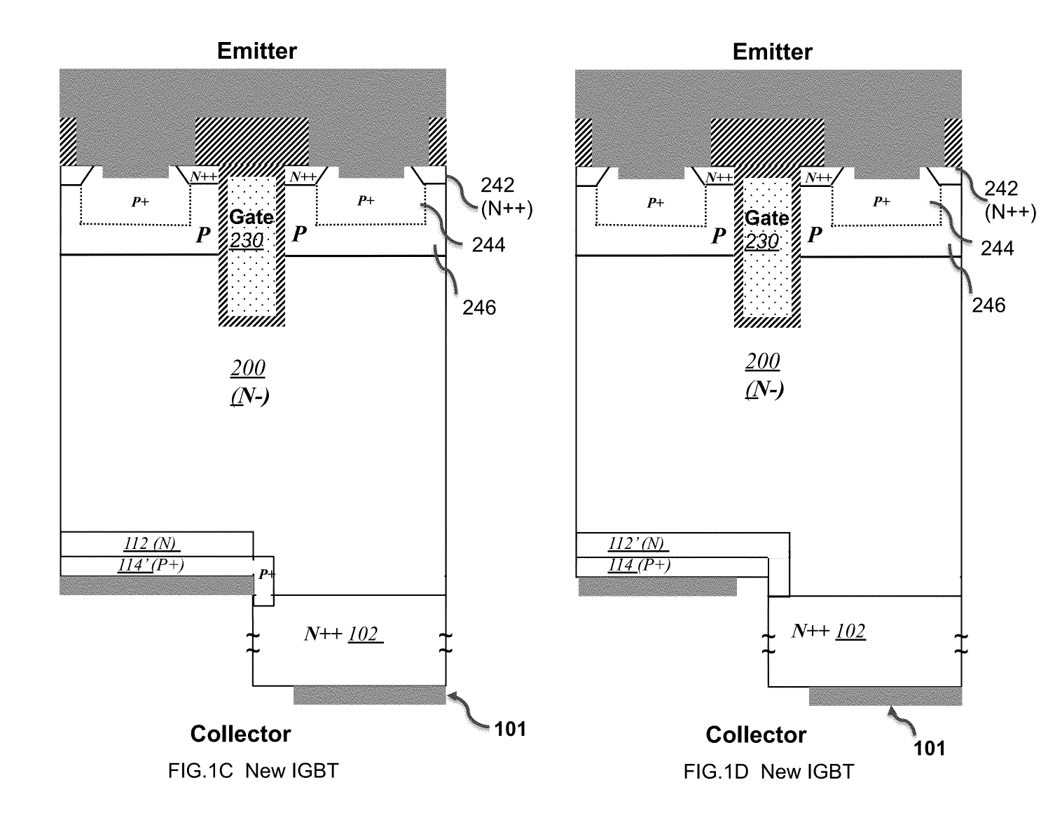

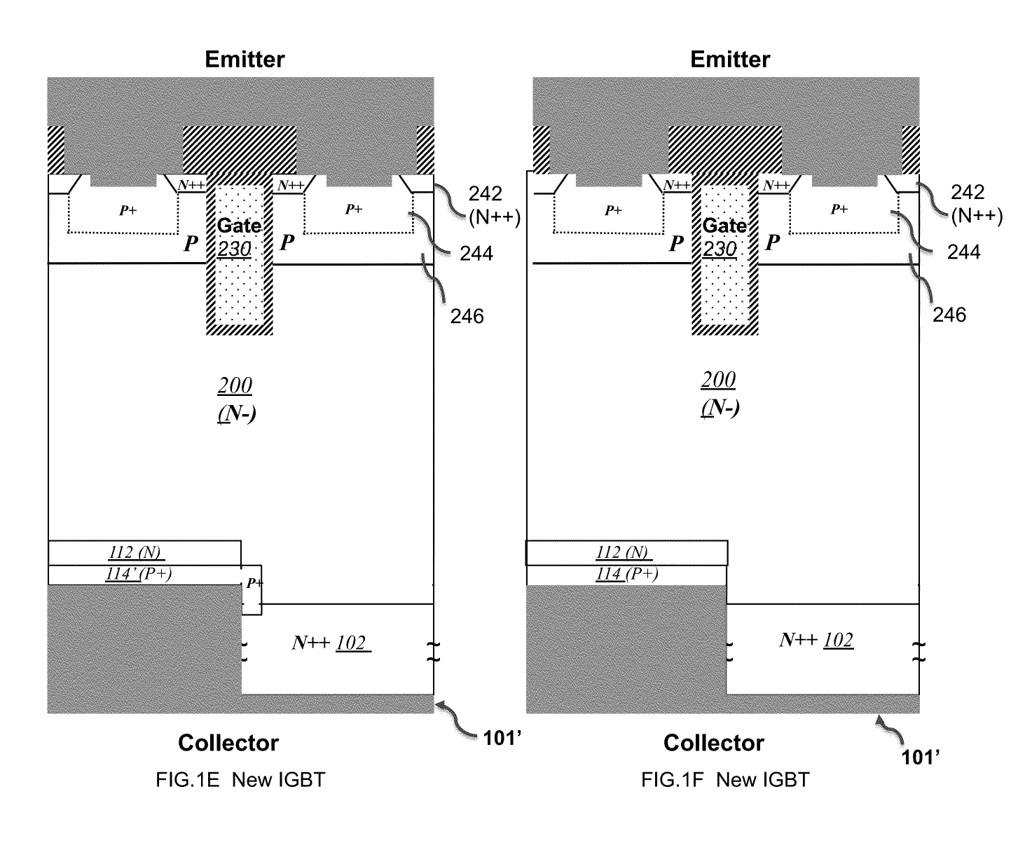

In FIG. 1B, the diode contact areas are underlain by a thick n++ diode contact region 102, which is the remnants of the former substrate. The collector 114 and the n-type buffer layer 112 are patterned, so as not to cover the diode contact areas. Collector metallization 101 makes ohmic contact to the diode contact region 102 and to collector 114.

FIG. 1A is generally similar to FIG. 1B, except that the collector 114′ is extended slightly, at its edge, to partially overhang the diode contact areas.

FIG. 1C is generally similar to FIG. 1A, except that the collector metallization 101 is not continuous. In this example separate connections are made to the collector areas and to the diode contact areas. Other elements are generally the same.

FIG. 1D is generally similar to FIG. 1B, except for two differences. First, as in FIG. 1C, the collector metallization 101 is not continuous. Second, and perhaps more important, the buffer layer 112′ overhangs the collector layer 114, and separates it from the n++ region 102.

FIG. 1E is generally similar to FIG. 1A, except that the collector metallization 101 (which was approximately conformal) has been replaced by a planarized metallization layer 101′. In this example separate connections are made to the collector areas and to the diode contact areas. Other elements are generally the same. The additional thickness of the planarized metallization layer 101′, combined with the rigidity of the thicker semiconductor material 102 in diode contact areas, provides additional protection against warping.

FIG. 1F is generally similar to FIG. 1E, except the collector layer 114 in FIG. 1F, unlike layer 114′ in FIG. 1E, does not overhang that the n++ region 102.

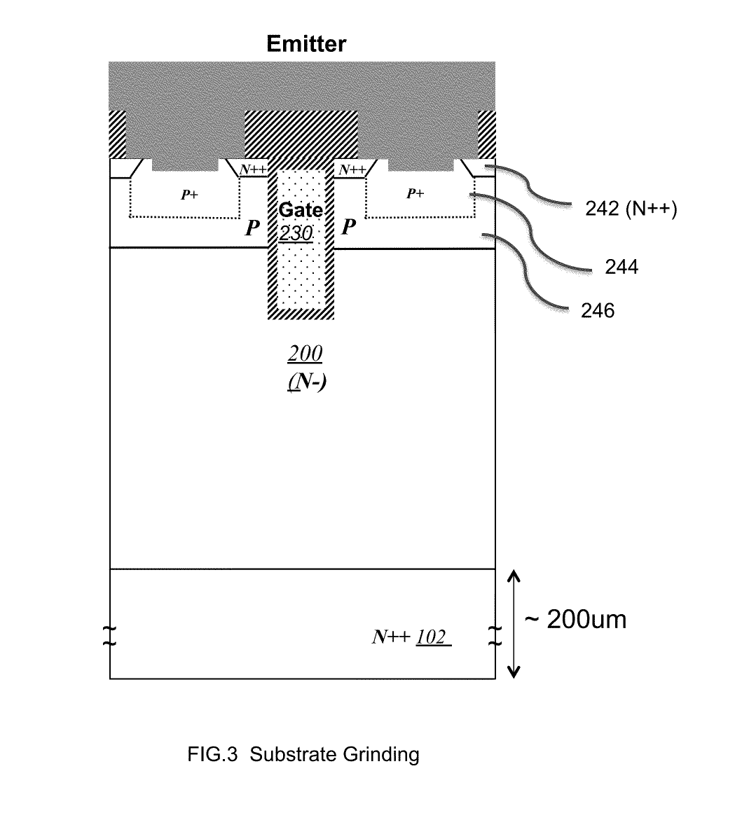

FIGS. 3-5 show some of the steps in making the structures of FIGS. 1A-1F. In the new process, the substrate is ground down to a normal thickness which can be handled by standard manufacturing equipment after completing the wafer front surface process. For example, the wafer thickness can be ground to 200 um, as illustrated in FIG. 3.

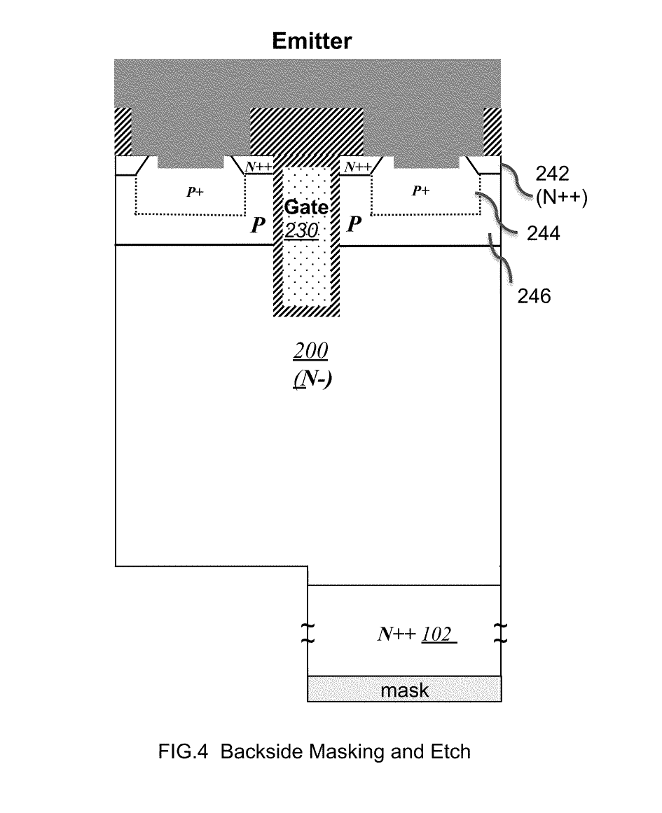

Then, a masking process is applied and the silicon is etched by a deep trench etch process. The etch process should cut through the N+ substrate layer. The depth of the etch should be properly controlled to avoid removing too much of the N− layer. This in turn avoids the degradation of the device's off-state breakdown voltage. This is depicted in FIG. 4.

In one example, where the semiconductor material has been ground to 200 microns, the back-surface trench can be etched to 130 microns deep. This leaves a thickness of 70 microns in the areas where the collector is present. However, as will be appreciated by those of ordinary skill in the art, the thickness of the active device areas will be adjusted based on voltage rating, drift layer doping, and other characteristics of the semiconductor material.

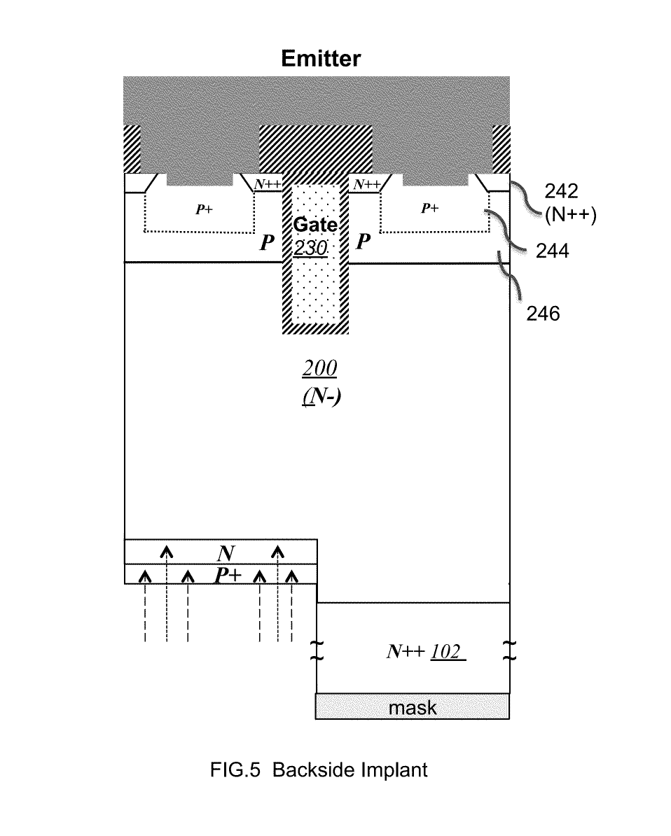

Next, N-type dopant (such as P or As) and P-type dopant (such as B) are implanted with different energies to form the shallow P+ anode (or collector) and N buffer layer as given in FIG. 5.

Subsequently, the masking layer is removed and a backside anneal is performed. This is followed by the standard backside metallization to produce any of the various final device structures shown in FIG. 1A, FIG. 1B, FIG. 1C, FIG. 1D, FIG. 1E, and FIG. 1F. These final device structures have the Field Stop layer and the transparent P+ anode residing at the trench bottom floor with the thick N+ substrate remainder to form the reverse conduction area or the “anode-short” layer. In addition, since the remaining N+ substrate has a normal thickness, it naturally becomes as a mechanical support to the whole wafer. Furthermore, the remaining N+ substrate also leads to the final device having a higher thermal capacitance compared to a thin substrate. As a result, the transient electro-thermal characteristic is expected to be superior compared to the conventional thin wafer FS-IGBT because of its higher thermal capacitance.

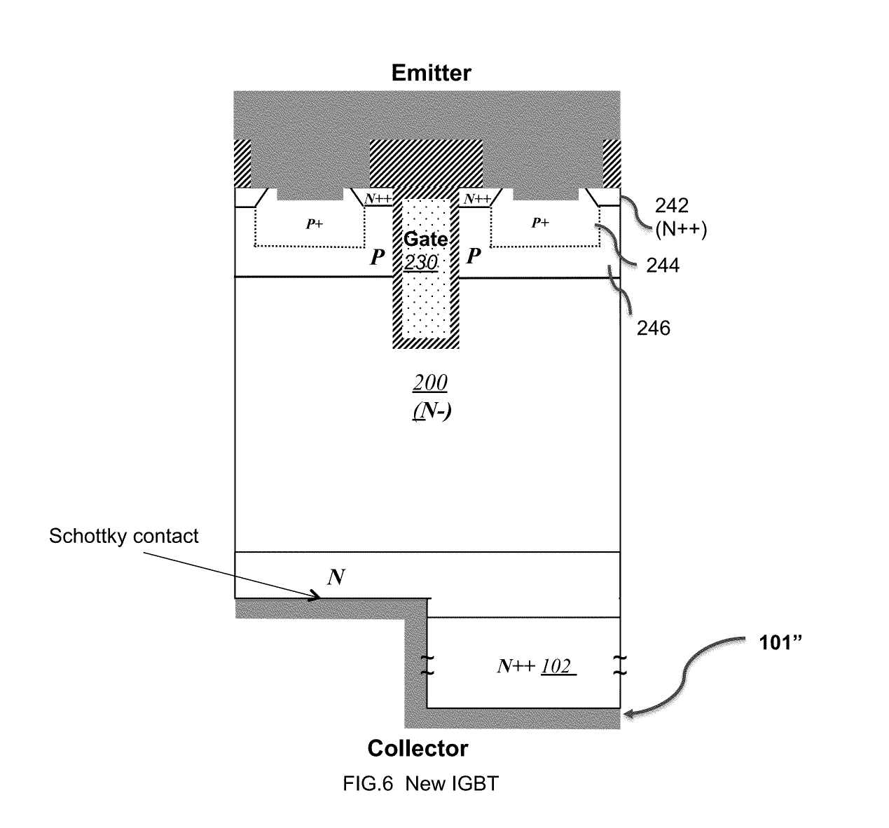

FIG. 6 is generally similar to FIG. 1B, except that the collector layer 114 has been replaced by Schottky metallization 101″, which forms a Schottky barrier contact with the overlying semiconductor material. Other elements are generally the same.

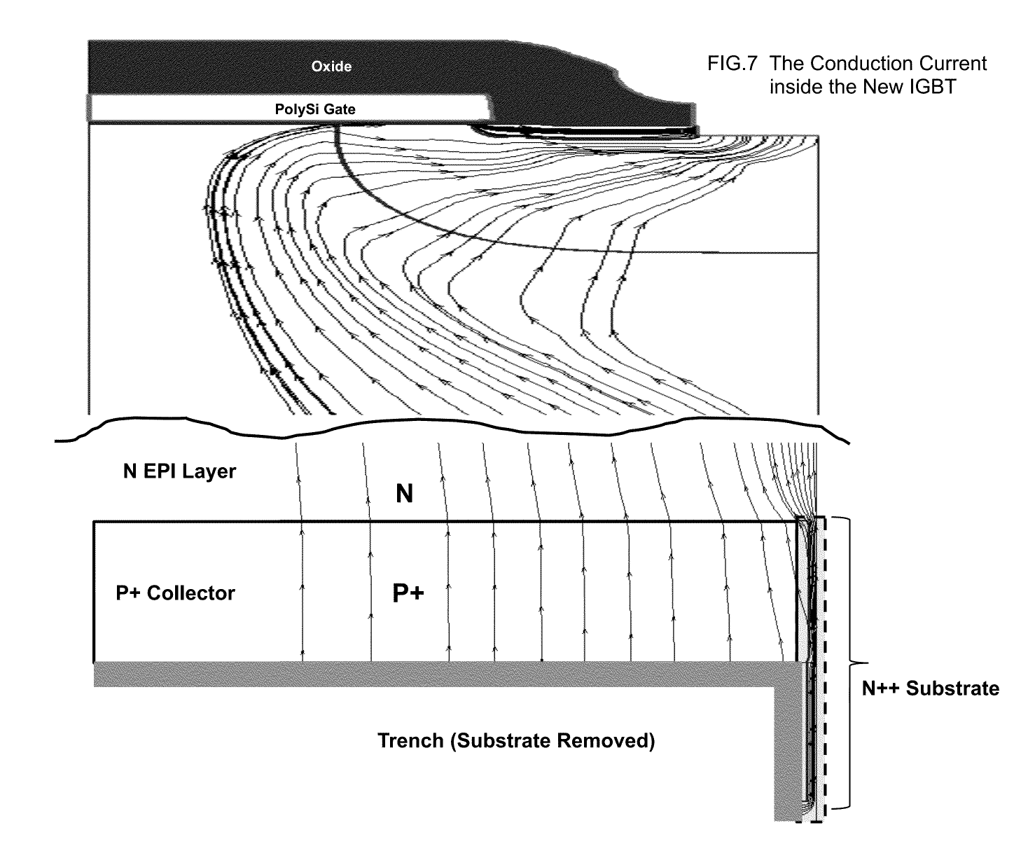

The forward current flow inside the new device with a planar gate is simulated by two-dimensional process and device CAD tool. The result is shown in FIG. 7. As can be seen, the electron current flowing through the thick N++ substrate turns on the P+Collector/N Epi junction. As a result, portions of the PN junction are forward biased and the forward conduction current flows through the P+Collector region.

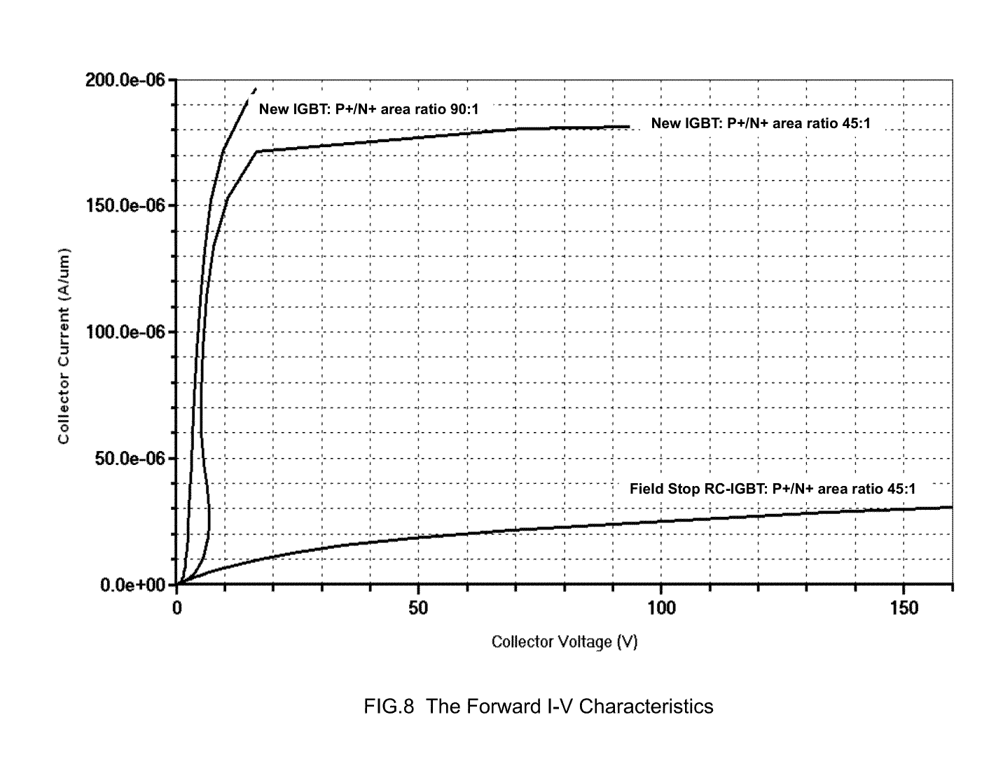

For comparison, the forward I-V characteristics of both a new IGBT (according to one sample embodiment of the present inventions) and a conventional Field Stop RC-IGBT are simulated and are given in FIG. 8. For a given area ratio (45:1) between the P+ region and N++ region, the current of the new structure is much higher than the conventional RC-IGBT. This is due to the thick N++ substrate, which has an exemplary thickness, here, of ˜225 um. This is a higher N++ resistance than that found in a conventional Field Stop RC-IGBT, which has a very shallow N++ region (˜1 um). The P+ collector/N-Epi junction in the new device is more easily turned on, which leads a higher hole injection from the P+ region. Moreover, by proper design of the P+/N++ area ratio, the “negative differential resistance” (NDR) can be completely eliminated in the new device, as depicted in FIG. 8.

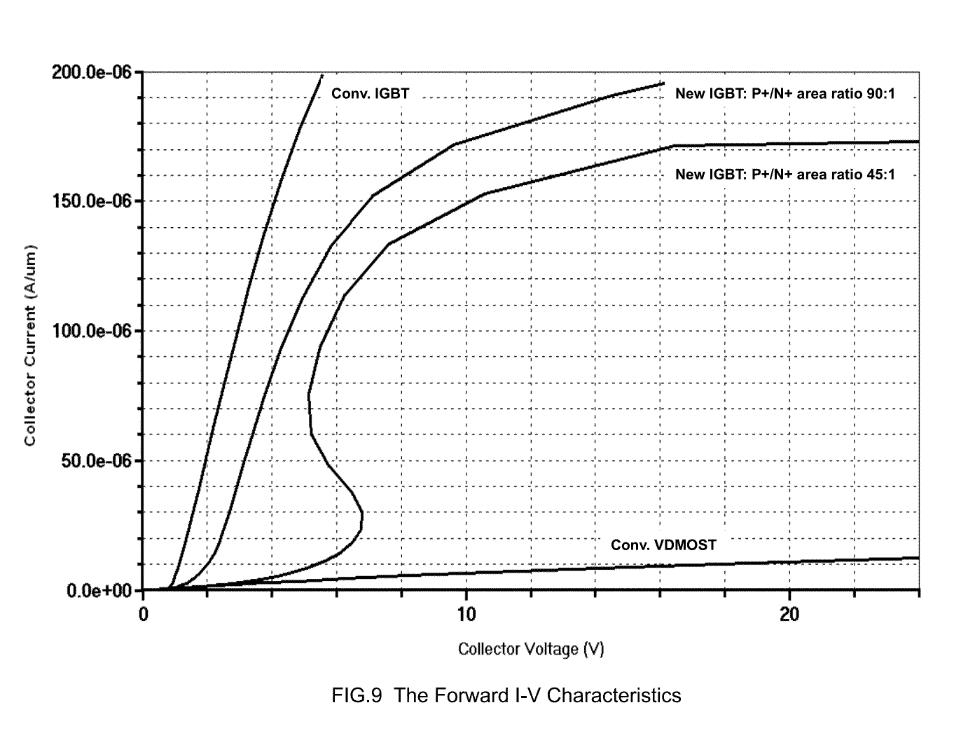

FIG. 9 compares the forward conduction I-V characteristics of a conventional IGBT, VDMOST, and one sample embodiment of the present inventions. As can be seen, the new device has a much higher current capability compared to the VDMOST. With proper design of the removal area of N++ substrate (P+ area), the forward conduction current of the new device can approach the conventional IGBT, which has no reverse conduction capability.

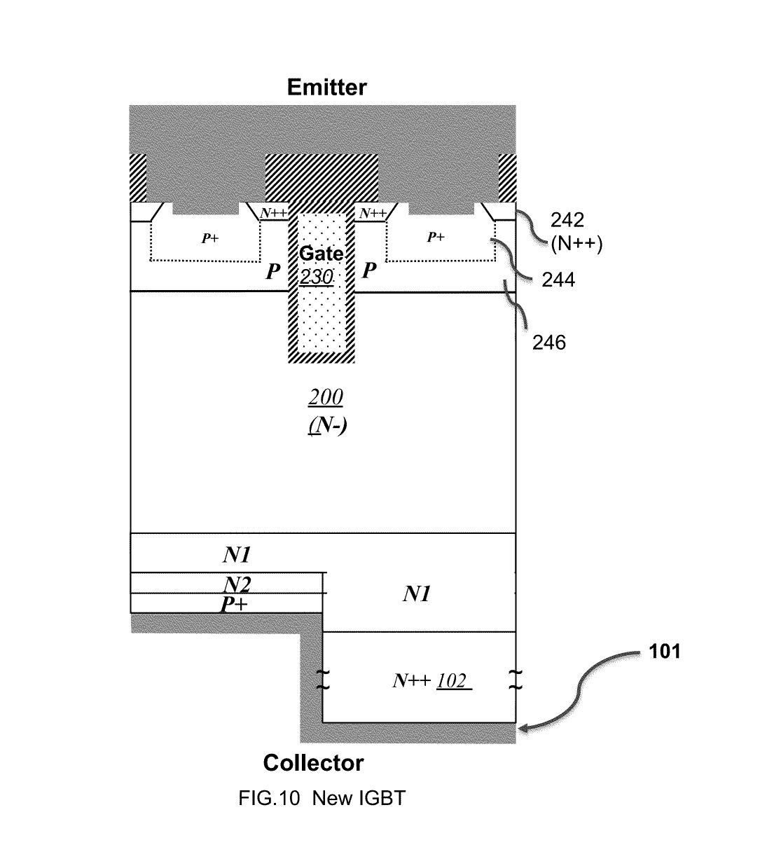

Moreover, by employing the innovative techniques of the instant application, many more advanced backside structures can be created to further improve IGBT characteristics. For example, the sample embodiment of FIG. 10 demonstrates a new IGBT with double buffer layers.

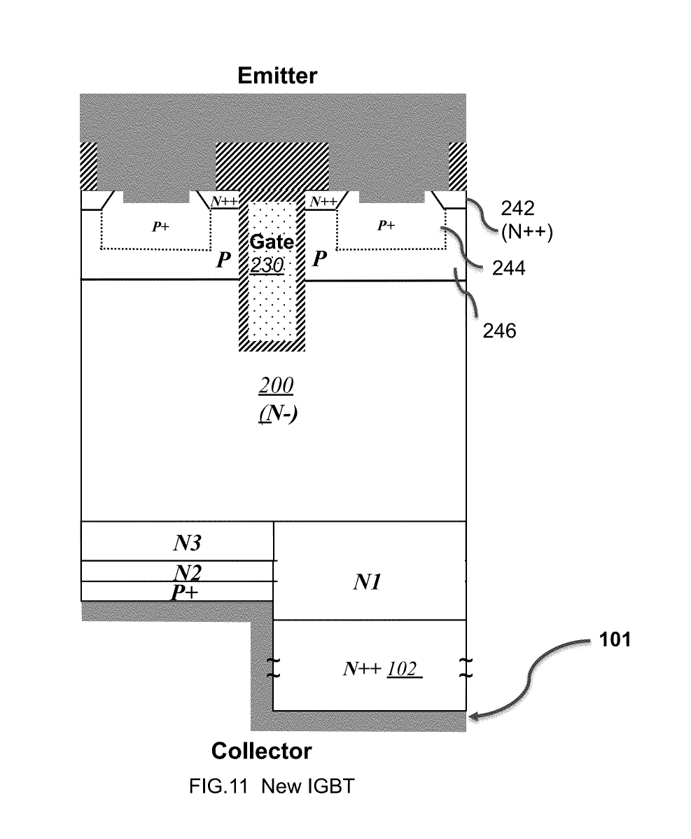

FIG. 11 displays a new IGBT according to the present inventions with triple-buffer layers having a segmented configuration, which is expected to produce further optimized characteristics of IGBT.

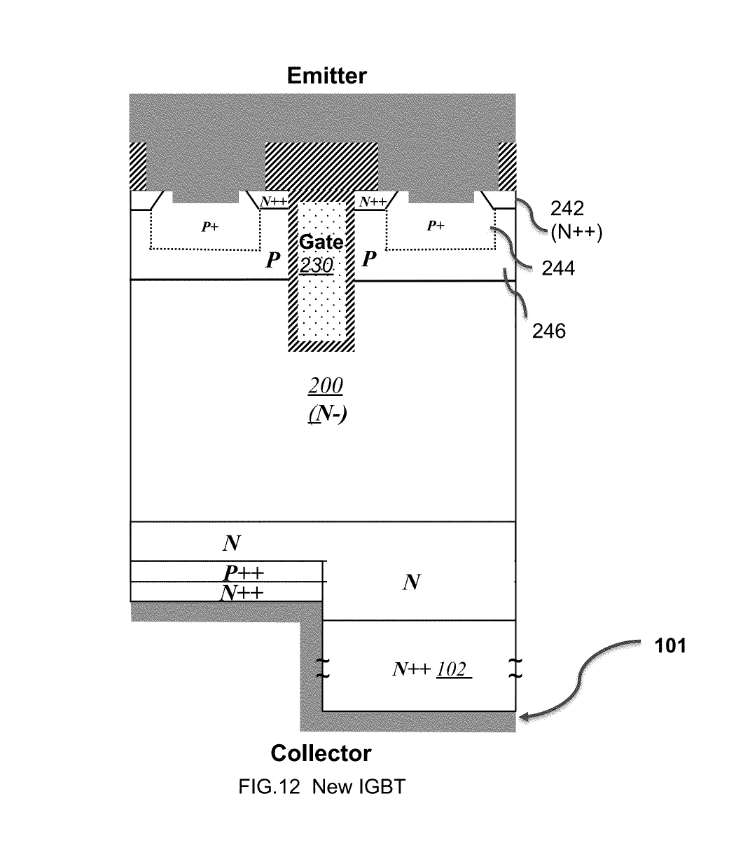

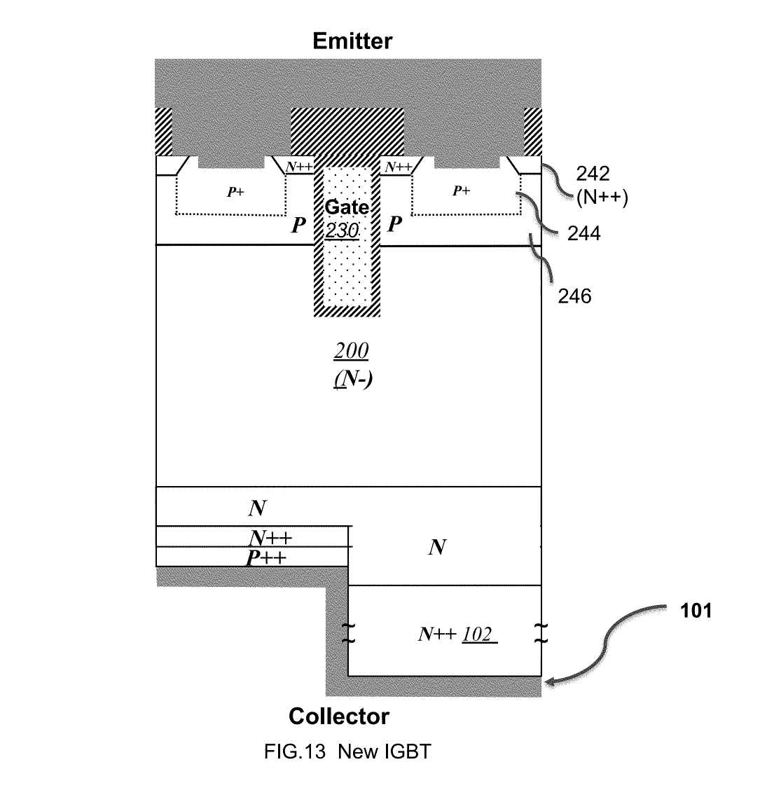

Additionally, the new processes can also be used for creating more advanced IGBTs with nano-layers of P++ and N++ by sub-keV implant process, as illustrated in the sample embodiments of FIG. 12 and FIG. 13. As can be seen, these IGBT structures have the tunneling anode structure bonding together with the anode short.

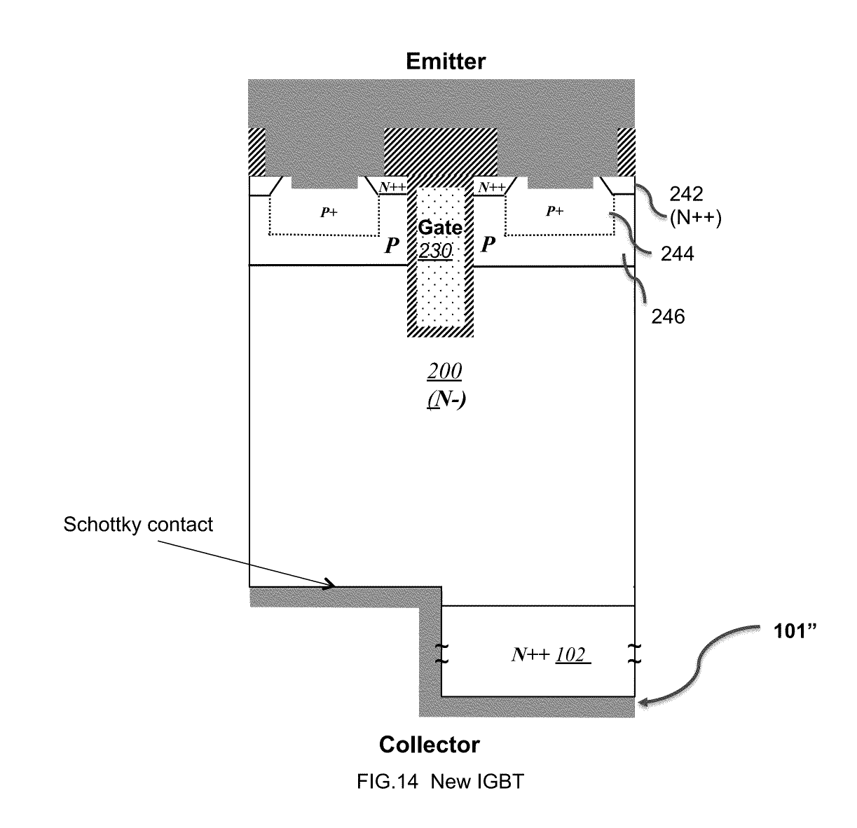

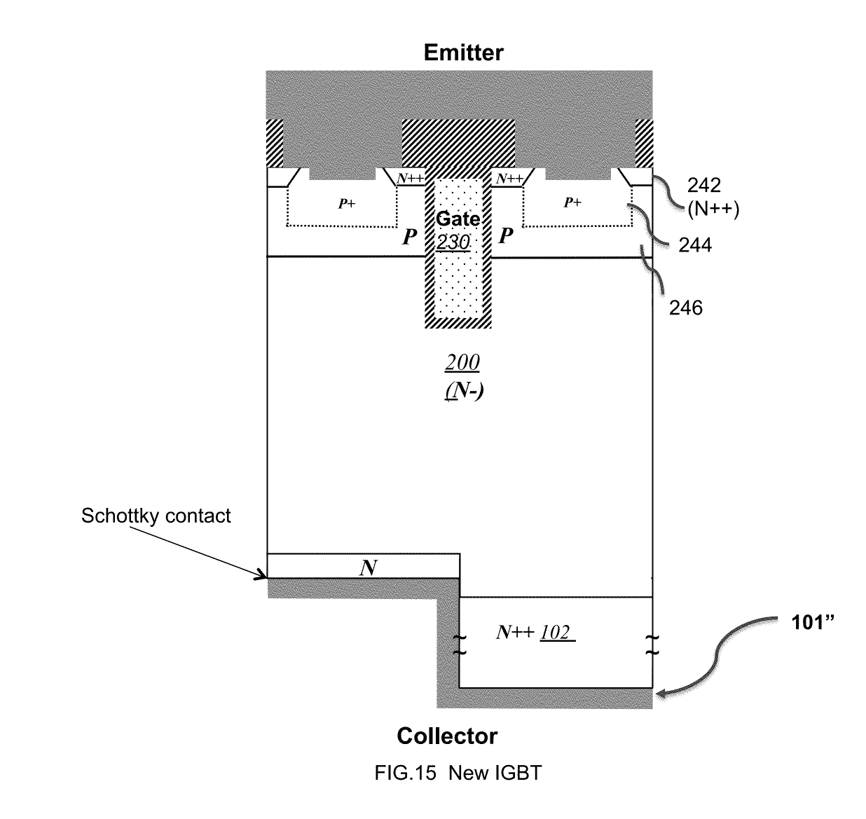

Furthermore, devices having a Schottky contact collector with the “shorted-anode” can be readily formed. Sample embodiments of these structures are depicted in FIG. 14 and FIG. 15.

The innovative teachings of the instant application can also be applied to devices with P++ substrate instead of N++ substrate.

### Advantages

The disclosed innovations, in various embodiments, provide one or more of at least the following advantages. However, not all of these advantages result from every one of the innovations disclosed, and this list of advantages does not limit the various claimed applications.
Better control of snapback effects;
Improved breakdown voltage;
Reduced forward voltage drop;
Increased thermal capacitance;
Improved transient electro-thermal characteristics;
Improvement on the trade-off between the forward current voltage drop, VCEsat, and the “negative differential resistance” (NDR) issue.

According to some but not necessarily all embodiments, there is provided: A reverse-conducting gated-base semiconductor device with bipolar conduction, comprising: an emitter structure, on a first surface of a first-type semiconductor die, which includes a second-type emitter region, and a control terminal which selectably connects a first-type source terminal to the bulk of the die; a collector structure, on a second surface of the semiconductor die, which includes a thin second-type collector region overlain by a first-type buffer layer; and a second-type reverse-conduction diode terminal, on the second surface; wherein the total thickness of the die, through the diode terminal, exceeds the total thickness of the die, through the collector structure.

According to some but not necessarily all embodiments, there is provided: A semiconductor device comprising: an emitter structure, on a first surface of a first-type semiconductor die, which includes a second-type emitter region; a collector structure which occupies only part of a second surface of the semiconductor die, and a diode structure which occupies other portions of the second surface; wherein the total thickness of the die, through the diode terminal, is more than twice the total thickness of the die, through the collector structure; and wherein the collector structure includes dopant components corresponding to a first diffusion length which is less than the diffusion length of dopant components of the second-type emitter region.

According to some but not necessarily all embodiments, there is provided: A reverse-conducting IGBT, comprising: an emitter structure, on a first side of a first-type semiconductor die, which includes a second-type emitter region, and a control terminal which selectably connects a first-type source terminal to the bulk of the die; a collector structure, on a second side of the semiconductor die, which includes a thin second-type collector region overland by a first-type buffer layer; a second-type reverse-conduction diode terminal, on the second side; wherein the total thickness of the die, through the diode terminal, exceeds the total thickness, through the collector structure.

According to some but not necessarily all embodiments, there is provided: A method for fabricating a reverse-conducting gated-base semiconductor device with bipolar conduction, comprising: providing a semiconductor die which includes both a heavily doped first-type substrate and a more lightly doped first-type drift region, and forming, on a first surface of the die, both a second-type emitter region and also a control terminal which selectably connects a first-type source terminal to the bulk of the die; etching recesses into a second surface of the semiconductor die, to thereby remove the substrate from recess locations and leave it in other locations; and forming a collector structure, in the recesses only; wherein the depth of the recesses is more then one-third of the total thickness of the die; whereby the remaining portions of the substrate on the second surface act as diode terminals, while the collector operates, with the emitter region, to conduct a bipolar current.

According to some but not necessarily all embodiments, there is provided: Reverse-conducting IGBTs where the collector side includes diode terminal regions, and the semiconductor material is much thicker through the diode terminal regions than it is through the collector regions. This exploits the area fraction which is taken up by the diode terminal regions to provide increased rigidity for the wafer, and thus avoid warping.

### Modifications and Variations

As will be recognized by those skilled in the art, the innovative concepts described in the present application can be modified and varied over a tremendous range of applications, and accordingly the scope of patented subject matter is not limited by any of the specific exemplary teachings given. It is intended to embrace all such alternatives, modifications and variations that fall within the spirit and broad scope of the appended claims.

While the primary examples described above are IGBTs, the disclosed inventions are also applicable to analogous devices which are not, strictly speaking, IGBTs.

More generally, the disclosed inventions can also be applied to any other device with bipolar conduction and back-surface carrier injection (especially if this carrier injection occurs over only part of the back surface). In such devices the ability to tailor a minority carrier injection structure using low-energy implants (or other shallow dopant introduction) and low Dt combines synergistically with the extra rigidity of the thickened sections which are not part of the minority carrier injection structure, but can make a thinned structure more stable.

It should also be noted that the disclosed innovations are not limited to silicon, but can be implemented in wafers of other semiconductor materials. Examples of such materials include SiGe, SiC, SiGeC, other IV-IV semiconductor alloys, III-V semiconductors, including tertiary and quaternary and other alloys, ZnS and other II-VI alloys, and any other semiconductor alloys which have carrier lifetimes long enough to make bipolar conduction practical.

A variety of patterns can be used for the diode areas 102. For example, in one contemplated class of implementations, the diode areas are laid out as spokes radiating from the center of the wafer, to enhance the stiffness of the wafer against warpage.

For another example, even though a trench gated structure is used for demonstration of the new technique in this application, the new technique can also be used in planar gated devices.

In another embodiment a similar process to that described above can be used, except that the wafer is ground before the top surface metal is deposited. In such case the top surface is covered by a dielectric material such as silicon dioxide. A similar back surface process is performed as described in FIGS. 3, 4 and 5 followed by the Emitter contact etch, top metal and back (Collector) metal deposition.

None of the description in the present application should be read as implying that any particular element, step, or function is an essential element which must be included in the claim scope: THE SCOPE OF PATENTED SUBJECT MATTER IS DEFINED ONLY BY THE ALLOWED CLAIMS. Moreover, none of these claims are intended to invoke paragraph six of 35 USC section 112 unless the exact words “means for” are followed by a participle.

The claims as filed are intended to be as comprehensive as possible, and NO subject matter is intentionally relinquished, dedicated, or abandoned.

1. A reverse-conducting gated-base semiconductor device with bipolar conduction, comprising:
a) an emitter structure, on a first surface of a first-type semiconductor die, which includes a second-type emitter region, and a control terminal which selectably connects a first-type source terminal to the bulk of the die;
b) a collector structure, on a second surface of the semiconductor die, which includes a thin second-type collector region overlain by a first-type buffer layer;
c) a second-type reverse-conduction diode terminal, on the second surface;
wherein the total thickness of the die, through the diode terminal, exceeds the total thickness of the die, through the collector structure.

2. The device of claim 1, wherein the total thickness of the die, through the diode terminal, is more than twice the total thickness through the collector structure.

3. The device of claim 1, wherein the first type is n-type, and the second type is p-type.

4. The device of claim 1, wherein the semiconductor die is silicon.

5. The device of claim 1, wherein the second-type emitter region is surrounded by a second-type body region, and wherein the control terminal is an insulated electrode which selectably inverts a portion of the body region.

6. The device of claim 1, wherein the device is an IGBT.

7. The device of claim 1, wherein the collector regions are located in recesses in the second surface of the die.

8. The device of claim 1, wherein the collector regions are located in recesses in the second surface of the die, and the diode terminals are not.

9. The device of claim 1, wherein the collector regions are located in recesses in the second surface of the die, which extend through more than half of the thickness of the semiconductor material of the die.

10. The device of claim 1, further comprising collector metallization which makes ohmic contact both to the diode terminals and to the collector regions.

11. The device of claim 1, further comprising collector-side metallization which forms a Schottky-barrier diode, on the second surface, with at least some first-type portions of the semiconductor die.

12. A semiconductor device comprising:
a) an emitter structure, on a first surface of a first-type semiconductor die, which includes a second-type emitter region;
b) a collector structure which occupies only part of a second surface of the semiconductor die, and c) a diode structure which occupies other portions of the second surface;
wherein the total thickness of the die, through the diode terminal, is more than twice the total thickness of the die, through the collector structure; and
wherein the collector structure includes dopant components corresponding to a first diffusion length which is less than the diffusion length of dopant components of the second-type emitter region.

13. The device of claim 12, wherein the first type is n-type, and the second type is p-type.

14. The device of claim 12, wherein the semiconductor die is silicon.

15. The device of claim 12, wherein the second-type emitter region is surrounded by a second-type body region, and wherein an insulated electrode which selectably inverts a portion of the body region, to thereby connect a first-type source region to the bulk of the semiconductor die.

16. The device of claim 12, wherein the device is an IGBT.

17. The device of claim 12, wherein the collector structures are located in etched recesses in the second surface of the die.

18. The device of claim 12, wherein the collector regions are located in recesses in the second surface of the die, and the diode terminals are not.

19. The device of claim 12, further comprising collector metallization which makes ohmic contact both to the diode terminals and to second-type portions of the collector regions.

20. (canceled)

21. A reverse-conducting IGBT, comprising:
a) an emitter structure, on a first side of a first-type semiconductor die, which includes a second-type emitter region, and a control terminal which selectably connects a first-type source terminal to the bulk of the die;
b) a collector structure, on a second side of the semiconductor die, which includes a thin second-type collector region overland by a first-type buffer layer;
c) a second-type reverse-conduction diode terminal, on the second side;
wherein the total thickness of the die, through the diode terminal, exceeds the total thickness, through the collector structure.

22-39. (canceled)
